(19) United States
(12) Patent Application Publication
(10) Pub. No.: US 2025/0120292 A1
(43) Pub. Date: Apr. 10, 2025

(54) METHOD OF MANUFACTURING DISPLAY APPARATUS

(71) Applicant: Samsung Display Co., Ltd., Yongin-si (KR)

(72) Inventors: Youngrok Kim, Yongin-si (KR); Woojin Cho, Yongin-si (KR)

(21) Appl. No.: 18/634,093

(22) Filed: Apr. 12, 2024

(30) Foreign Application Priority Data
Oct. 5, 2023 (KR) 10-2023-0132701

(51) Int. Cl. H10K 59/80; H10K 59/12; H10K 59/123; H10K 59/131; H10K 59/35

(52) U.S. Cl. CPC H10K 59/878; H10K 59/1201; H10K 59/123; H10K 59/131; H10K 59/35

(57) ABSTRACT

A method of manufacturing a display apparatus includes locating a first inorganic layer on a substrate, locating a reflector on the first inorganic layer, locating a second inorganic layer on the reflector, and locating an organic light-emitting diode on the second inorganic layer, wherein the locating of the reflector includes forming a groove portion in the first inorganic layer, locating a reflective layer on the first inorganic layer to cover the first inorganic layer, and polishing the reflective layer.

This application claims priority to Korean Patent Application No. 10-2023-0132701, filed on Oct. 5, 2023, and all the benefits accruing therefrom under 35 U.S.C. § 119, the content of which in its entirety is herein incorporated by reference.

### BACKGROUND

### 1. Field

One or more embodiments relate to a method, and more particularly, to a method of manufacturing a display apparatus.

### 2. Description of the Related Art

Mobility-based electronic devices are widely used. Recently, tablet personal computers (PCs), in addition to small electronic devices such as mobile phones, have been widely used as mobile electronic devices.

A mobile electronic device includes a display apparatus for providing visual information, such as an image, to a user, in order to support various functions. Recently, as other components for driving a display apparatus have been miniaturized, the proportion of the display apparatus in an electronic device has gradually increased, and a structure that is bendable at a certain angle from a flat state has been developed.

### SUMMARY

One or more embodiments are aimed at processing a reflector including a silver material by using a damascene method.

Additional aspects will be set forth in the description which follows and will be apparent from the description.

According to one or more embodiments, a method of manufacturing a display apparatus includes locating a first inorganic layer on a substrate, locating a reflector on the first inorganic layer, locating a second inorganic layer on the reflector, and locating an organic light-emitting diode on the second inorganic layer, wherein the locating of the reflector includes forming a groove portion in the first inorganic layer, locating a reflective layer on the first inorganic layer to cover the first inorganic layer, and polishing the reflective layer.

In an embodiment, the locating of the reflector may further include locating an adhesive layer on the first inorganic layer to cover the first inorganic layer, wherein the locating of the reflective layer includes locating the reflective layer on the adhesive layer.

In an embodiment, the adhesive layer may contact an inner peripheral surface of the groove portion.

In an embodiment, the reflector may include a silver (Ag) material.

In an embodiment, the reflector may include a first reflector, a second reflector spaced apart from the first reflector, and a third reflector spaced apart from the first reflector and the second reflector, wherein the organic light-emitting diode includes a first organic light-emitting diode overlapping the first reflector, a second organic light-emitting diode overlapping the second reflector, and a third organic light-emitting diode overlapping the third reflector.

In an embodiment, the locating of the second inorganic layer may include locating a 2-1 inorganic layer on the reflector, locating a 2-2 inorganic layer on the 2-1 inorganic layer, and locating a 2-3 inorganic layer on the 2-2 inorganic layer, wherein the first organic light-emitting diode is located on the 2-1 inorganic layer, the second organic light-emitting diode is located on the 2-2 inorganic layer, and the third organic light-emitting diode is located on the 2-3 inorganic layer.

In an embodiment, the locating of the second inorganic layer may further include etching parts of the 2-2 inorganic layer and the 2-3 inorganic layer overlapping the first reflector, and etching a part of the 2-3 inorganic layer overlapping the second reflector.

In an embodiment, each of the etching of the parts of the 2-2 inorganic layer and the 2-3 inorganic layer and the etching of the part of the 2-3 inorganic layer may include a photolithography process.

In an embodiment, a distance from the first reflector to the first organic light-emitting diode, a distance from the second reflector to the second organic light-emitting diode, and a distance from the third reflector to the third organic light-emitting diode may sequentially increase.

In an embodiment, the 2-1 inorganic layer and the 2-2 inorganic layer may include different materials.

In an embodiment, the 2-2 inorganic layer and the 2-3 inorganic layer may include different materials.

In an embodiment, the first organic light-emitting diode may emit red light, the second organic light-emitting diode may emit green light, and the third organic light-emitting diode may emit blue light.

According to one or more embodiments, a method of manufacturing a display apparatus includes locating a first inorganic layer on a substrate, locating a first reflector, a second reflector, and a third reflector on the first inorganic layer to be spaced apart from each other, locating a 2-1 inorganic layer on the first reflector, the second reflector, and the third reflector, locating a 2-2 inorganic layer on the 2-1 inorganic layer, locating a 2-3 inorganic layer on the 2-2 inorganic layer, etching parts of the 2-2 inorganic layer and the 2-3 inorganic layer overlapping the first reflector, etching a part of the 2-3 inorganic layer overlapping the second reflector, locating a first organic light-emitting diode on the 2-1 inorganic layer to overlap the first reflector, locating a second organic light-emitting diode on the 2-2 inorganic layer to overlap the second reflector, and locating a third organic light-emitting diode on the 2-3 inorganic layer to overlap the third reflector.

In an embodiment, a distance from the first reflector to the first organic light-emitting diode, a distance from the second reflector to the second organic light-emitting diode, and a distance from the third reflector to the third organic light-emitting diode may sequentially increase.

In an embodiment, the 2-1 inorganic layer and the 2-2 inorganic layer may include different materials.

In an embodiment, the 2-2 inorganic layer and the 2-3 inorganic layer may include different materials.

In an embodiment, the first organic light-emitting diode may emit red light, the second organic light-emitting diode may emit green light, and the third organic light-emitting diode may emit blue light.

In an embodiment, an adhesive layer may be located between the first inorganic layer and the first reflector, between the first inorganic layer and the second reflector, and between the first inorganic layer and the third reflector.

In an embodiment, each of the first reflector, the second reflector, and the third reflector may include a silver (Ag) material.

In an embodiment, each of the etching of the parts of the 2-2 inorganic layer and the 2-3 inorganic layer and the etching of the part of the 2-3 inorganic layer may include a photolithography process.

Other aspects, features, and advantages of the invention will become more apparent from the drawings, the claims, and the detailed description.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic plan view of a display apparatus, according to an embodiment;

FIG. 2 is an equivalent circuit diagram illustrating one pixel included in a display apparatus, according to an embodiment;

FIG. 3 is a cross-sectional view illustrating a display apparatus, according to an embodiment;

FIG. 4 is a schematic cross-sectional view illustrating a part of a display apparatus, according to an embodiment;

FIG. 5 is a schematic cross-sectional view illustrating a part of a display apparatus, according to an embodiment;

FIG. 6 is a schematic cross-sectional view illustrating a part of a display apparatus, according to an embodiment;

FIG. 7 is a schematic cross-sectional view illustrating a part of a display apparatus, according to an embodiment;

FIG. 8 is a schematic cross-sectional view illustrating a part of a display apparatus, according to an embodiment;

FIG. 9 is a schematic cross-sectional view illustrating a part of a display apparatus, according to an embodiment;

FIG. 10 is a schematic cross-sectional view illustrating a part of a display apparatus, according to an embodiment;

FIG. 11 is a schematic cross-sectional view illustrating a part of a display apparatus, according to an embodiment;

FIG. 12 is a schematic cross-sectional view illustrating a part of a display apparatus, according to an embodiment;

FIG. 13 is a schematic cross-sectional view illustrating a part of a display apparatus, according to an embodiment

FIG. 14 is a schematic cross-sectional view illustrating a part of a display apparatus, according to an embodiment; and

FIG. 15 is a schematic flowchart illustrating a method of manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the invention may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the invention, and methods for achieving them will be clarified with reference to embodiments described below in detail with reference to the drawings. However, the invention is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise. The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that the terms “including,” and “having,” are intended to indicate the existence of the features or elements described in the specification and are not intended to preclude the possibility that one or more other features or elements may exist or may be added.

It will be further understood that, when a layer, region, or component is referred to as being “on” another layer, region, or component, it may be disposed directly on the other layer, region, or component, or may be indirectly on the other layer, region, or component with intervening layers, regions, or components therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Sizes of components in the drawings may be exaggerated or reduced for convenience of explanation. For example, because sizes and thicknesses of elements in the drawings are arbitrarily illustrated for convenience of explanation, the disclosure is not limited thereto.

In the following embodiments, the x-axis, the y-axis and the z-axis are not limited to three axes of the rectangular coordinate system and may be interpreted in a broader sense. For example, the x-axis, the y-axis, and the z-axis may be perpendicular to one another, or may represent different directions that are not perpendicular to one another.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

When a certain embodiment may be implemented differently, a specific process order may be different from the described order. For example, two consecutively described processes may be performed substantially at the same time or may be performed in an order opposite to the described order.

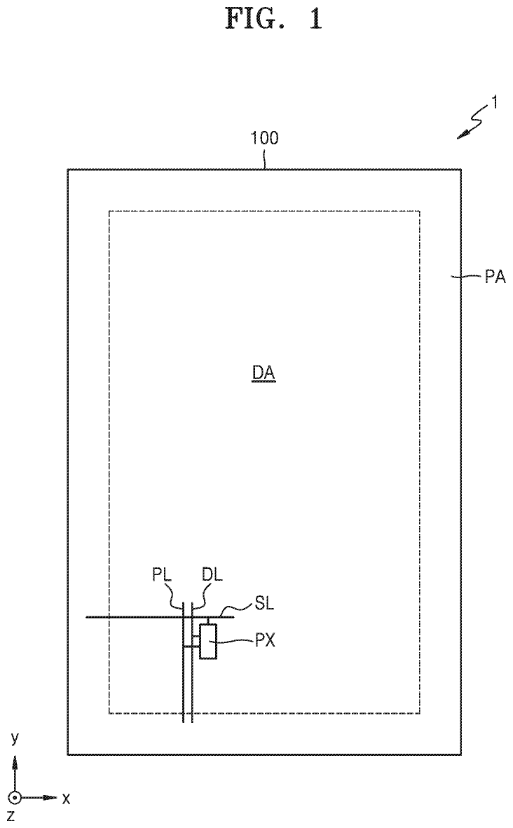

FIG. 1 is a schematic plan view illustrating a display apparatus 1, according to an embodiment.

In an embodiment, the display apparatus 1 may be any of various devices such as a smartphone, a tablet, a laptop, a television, or a billboard. The display apparatus 1 includes thin-film transistors and a capacitor, and the thin-film transistors and the capacitor may be implemented by conductive layers and insulating layers.

In an embodiment, the display apparatus 1 includes a display area DA and a peripheral area PA located outside the display area DA. In FIG. 1, the display area DA has a rectangular shape. However, the invention is not limited thereto. The display area DA may have any of various shapes such as a circular shape, an elliptical shape, a polygonal shape, or a specific shape.

In an embodiment, the display area DA is a portion where an image is displayed, and a plurality of pixels PX may be located in the display area DA. Each pixel PX may include a display device such as an organic light-emitting diode. Each pixel PX may emit, for example, red light, green light, or blue light. The pixel PX may be connected to a pixel circuit including a thin-film transistor (TFT) and a storage capacitor. The pixel circuit may be connected to a scan line SL through which a scan signal is transmitted, a data line DL that intersects the scan line SL and through which a data signal is transmitted, and a driving voltage line PL through which a driving voltage is supplied. The scan line SL may extend in a first direction (e.g., an x-axis direction), and the data line DL and the driving voltage line PL may extend in a second direction (e.g., a y-axis direction) intersecting the first direction (e.g., the x-axis direction).

In an embodiment, the pixel PX may emit light having a luminance corresponding to an electrical signal from the pixel circuit that is electrically connected to the pixel PX. The display area DA may display a certain image through light emitted from the pixel PX. For reference, as described above, the pixel PX may be defined as an emission area that emits light of any one of red, green, and blue colors.

In an embodiment, the peripheral area PA may be a portion where the pixel PX is not located and an image is not displayed. In the peripheral area PA, a power supply wiring for driving the pixel PX may be located. Also, in the peripheral area PA, pads may be located, and an integrated circuit device such as a driver IC or a printed circuit board including a driving circuit unit may be electrically connected to the plurality of pads.

In an embodiment, because the display apparatus 1 includes a substrate 100, the substrate 100 may include the display area DA and the peripheral area PA. The substrate 100 will be described below in detail.

In an embodiment, a plurality of transistors may be located in the display area DA. In the plurality of transistors, a first terminal of the transistor may be a source electrode or a drain electrode, and a second terminal may be an electrode different from the first terminal, according to a type (N-type or P-type) and/or an operating condition of the transistor. For example, when the first terminal is a source electrode, the second terminal may be a drain electrode.

In an embodiment, the plurality of transistors may include a driving transistor, a data write transistor, a compensation transistor, an initialization transistor, and an emission control transistor. The driving transistor may be connected between the driving voltage line PL and an organic light-emitting diode OLED, and the data write transistor may be connected to the data line DL and the driving transistor and may perform a switching operation of transmitting a data signal transmitted through the data line DL.

In an embodiment, the compensation transistor may be turned on according to a scan signal received through the scan line SL to connect the driving transistor to the organic light-emitting diode OLED and compensate for a threshold voltage of the driving transistor.

In an embodiment, the initialization transistor may be turned on according to a scan signal received through the scan line SL to transmit an initialization voltage to a gate electrode of the driving transistor and initialize the gate electrode of the driving transistor. The scan line connected to the initialization transistor may be a separate scan line different from the scan line connected to the compensation transistor.

In an embodiment, the emission control transistor may be turned on according to an emission control signal received through an emission control line so that driving current flows through the organic light-emitting diode OLED.

In an embodiment, the organic light-emitting diode OLED may include a pixel electrode (anode) and a counter electrode (cathode), and the counter electrode may receive a second power supply voltage ELVSS. The organic light-emitting diode OLED may receive the driving current from the driving transistor to emit light and display an image.

Hereinafter, although an organic light-emitting display apparatus is described as a display apparatus according to an embodiment, the display apparatus of the invention is not limited thereto. In another embodiment, the display apparatus of the invention may be an inorganic light-emitting display apparatus or an inorganic electroluminescent (EL) display apparatus, or a quantum dot light-emitting display apparatus. For example, an emission layer of a display device included in the display apparatus may include an organic material or an inorganic material. Also, the display apparatus may include an emission layer and quantum dots located in a path of light emitted from the emission layer.

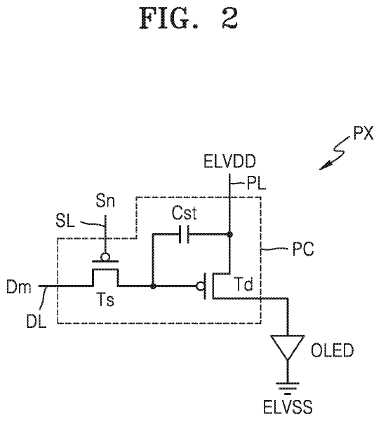

FIG. 2 is an equivalent circuit diagram illustrating one pixel included in the display apparatus 1, according to an embodiment.

In an embodiment and as shown in FIG. 2, each pixel PX includes a pixel circuit PC connected to the scan line SL and the data line DL, and an organic light-emitting diode OLED connected to the pixel circuit PC. The pixel circuit PC includes a driving thin-film transistor Td, a switching thin-film transistor Ts, and a storage capacitor Cst. The switching thin-film transistor Ts is connected to the scan line SL and the data line DL, and transmits a data signal Dm input through the data line DL to the driving thin-film transistor Td according to a scan signal Sn input through the scan line SL.

In an embodiment, the storage capacitor Cst is connected to the switching thin-film transistor Ts and the driving voltage line PL, and stores a voltage corresponding to a difference between a voltage received from the switching thin-film transistor Ts and a first power supply voltage ELVDD supplied to the driving voltage line PL. A second power supply voltage ELVSS may be a driving voltage having a lower level than the first power supply voltage ELVDD. A level of a driving voltage supplied to each pixel PX may be a difference between levels of the first power supply voltage ELVDD and the second power supply voltage ELVSS.

In an embodiment, the driving thin-film transistor Td may be connected to the driving voltage line PL and the storage capacitor Cst, and may control driving current flowing through the organic light-emitting diode OLED from the driving voltage line PL in response to a value of the voltage stored in the storage capacitor Cst. The organic light-emitting diode OLED may emit light having a certain luminance due to the driving current.

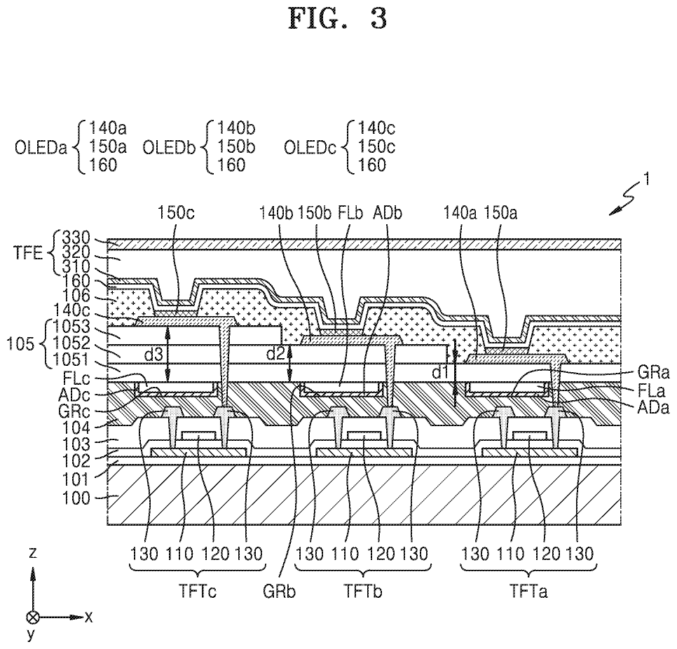

FIG. 3 is a cross-sectional view illustrating the display apparatus 1, according to an embodiment.

In an embodiment and referring to FIG. 3, the display apparatus 1 may include the substrate 100, a buffer layer 101, thin-film transistors (e.g., TFTa, TFTb, and TFTc), a gate insulating film 102, an interlayer insulating film 103, a first inorganic layer 104, reflectors (e.g., FLa, FLb, and FLc), adhesive members (e.g., ADa, ADb, and ADc), a second inorganic layer 105, organic light-emitting didoes (e.g., OLEDa, OLEDb, and OLEDc), a pixel-defining film 106, and a thin-film encapsulation layer TFE.

In an embodiment, the substrate 100 may include any of various flexible or bendable materials. For ultra-high resolution, the substrate 100 included in the display apparatus may include a semiconductor material, for example, a group IV semiconductor, a group III-V compound semiconductor, or a group II-VI compound semiconductor. The substrate 100 may include a silicon layer. That is, the substrate 100 may be a semiconductor substrate 100 including a semiconductor material. As such, an OLED display using the substrate 100 including a semiconductor material may be referred to as an OLED on silicon (“OLEDOS”). OLEDOS may be mainly used in extended reality (XR), and may have ultra-high definition of 8 K or more in a small area of about 1 to 2 inches. When the semiconductor substrate 100 is used, pixels arranged at ultra-high resolution may be closely controlled.

In an embodiment, a type of the substrate 100 is not limited to the semiconductor substrate 100. For example, the substrate 100 may include glass, a metal, or a polymer resin. Also, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications may be made. For example, the substrate 100 may have a multi-layer structure including two layers each including a polymer resin and a barrier layer including an inorganic material (e.g., silicon oxide, silicon nitride, or silicon oxynitride) and located between the two layers.

In an embodiment, the buffer layer 101 may be located on the substrate 100. The buffer layer 101 may function as a barrier layer and/or a blocking layer for preventing diffusion of impurity ions, preventing penetration of moisture or external air, and planarizing a surface. The buffer layer 101 may include silicon oxide, silicon nitride, or silicon oxynitride. The buffer layer 101 may adjust a heat supply rate during a crystallization process for forming a semiconductor layer 110 described below so that the semiconductor layer 110 is uniformly crystalized.

In an embodiment, the thin-film transistors (e.g., TFTa, TFTb, and TFTc) may be located on the buffer layer 101. A plurality of thin-film transistors (e.g., TFTa, TFTb, and TFTc) may be provided. For example, a first thin-film transistor TFTa, a second thin-film transistor TFTb, and a third thin-film transistor TFTc may be located on the buffer layer 101 to be spaced apart from each other. Each of the first to third thin-film transistors TFTa, TFTb, and TFTc, respectively, may include the semiconductor layer 110, a gate layer 120, and a conductive layer 130.

In an embodiment, the semiconductor layer 110 may be located on the buffer layer 101. The semiconductor layer 110 may be formed of polysilicon, and may include a channel region not doped with impurities and a source region and a drain region formed by doping impurities on both sides of the channel region. The impurities may vary according to a type of a thin-film transistor, and may be N-type impurities or P-type impurities.

In an embodiment, the gate insulating film 102 may be located on the semiconductor layer 110. The gate insulating film 102 may be an element for ensuring insulation between the semiconductor layer 110 and the gate layer 120. The gate insulating film 102 may include an inorganic material such as silicon oxide, silicon nitride, and/or silicon oxynitride, and may be located between the semiconductor layer 110 and the gate layer 120. Also, the gate insulating film 102 may be formed to correspond to an entire surface of the substrate 100, and may have a structure in which contact holes are formed at preset portions. As such, an insulating film including an inorganic material may be formed by using chemical vapor deposition (CVD) or atomic layer deposition (ALD). This applies to the following embodiments and modifications thereof.

In an embodiment, the gate layer 120 may be located on the gate insulating film 102. The gate layer 120 may vertically overlap the semiconductor layer 110, and may include at least one metal from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (W).

In an embodiment, the interlayer insulating film 103 may be located on the gate layer 120. The interlayer insulating film 103 may cover the gate layer 120. The interlayer insulating film 103 may be formed of an inorganic material. For example, the interlayer insulating film 103 may be formed of a metal oxide or a metal nitride. In detail, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZrO₂). The interlayer insulating film 103 may have a double structure formed of SiOₓ/SiN_{y} or SiNₓ/SiO_{y} in some embodiments.

In an embodiment, the conductive layer 130 may be located on the interlayer insulating film 103. The conductive layer 130 may function as an electrode connected to the source/drain region of the semiconductor layer 110 through a through-hole formed in the interlayer insulating film 103. The conductive layer 130 may include at least one metal selected from among aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the conductive layer 130 may include a Ti layer, an Al layer, and/or a Cu layer.

In an embodiment, the first inorganic layer 104 may be located on the conductive layer 130. The first inorganic layer 104 may cover an upper portion of the conductive layer 130 and may have a substantially flat top surface. The first inorganic layer 104 may be formed of an inorganic material. For example, the first inorganic layer 104 may be formed of a metal oxide or a metal nitride. In detail, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZrO₂). The first inorganic layer 104 may have a double structure formed of SiOₓ/SiN_{y} or SiNₓ/SiO_{y} in some embodiments.

In an embodiment, the first inorganic layer 104 may include groove portions (e.g., GRa, GRb, and GRc). The groove portions (e.g., GRa, GRb, and GRc) may be recessed from a top surface of the first inorganic layer 104. The groove portions (e.g., GRa, GRb, and GRc) may overlap the first to third thin-film transistors TFTa, TFTb, and TFTc. For example, the groove portions (e.g., GRa, GRb, and GRc) may have quadrangular cross-sectional shapes. However, this is merely an example, and shapes of the groove portions (e.g., GRa, GRb, and GRc) are not limited thereto.

In an embodiment, a plurality of groove portions (e.g., GRa, GRb, and GRc) may be provided. The number of groove portions (e.g., GRa, GRb, and GRc) may correspond to the number of thin-film transistors (e.g., TFTa, TFTb, and TFTc). For example, the groove portions (e.g., GRa, GRb, and GRc) may include a first groove portion GRa, a second groove portion GRb, and a third groove portion GRc. The first groove portion GRa, the second groove portion GRb, and the third groove portion GRc may be spaced apart from each other. The first groove portion GRa may correspond to the first thin-film transistor TFTa, the second groove portion GRb may correspond to the second thin-film transistor TFTb, and the third groove portion GRc may correspond to the third thin-film transistor TFTc.

In an embodiment, the reflectors (e.g., FLa, FLb, and FLc) may be located on the first inorganic layer 104. The reflectors (e.g., FLa, FLb, and FLc) may include a material that reflects light. The reflectors (e.g., FLa, FLb, and FLc) may include a metal material. For example, the reflectors (e.g., FLa, FLb, and FLc) may include a silver (Ag) material. The reflectors (e.g., FLa, FLb, and FLc) may be accommodated in the first groove portion GRa, the second groove portion GRb and the third groove portion GRc, respectively. Shapes of the reflectors (e.g., FLa, FLb, and FLc) may correspond to shapes of the first groove portion GRa, the second groove portion GRb and the third groove portion GRc, respectively. For example, when the first to third groove portions GRa, GRb, and GRc, respectively, have quadrangular cross-sectional shapes, the reflectors (e.g., FLa, FLb, and FLc) may also have quadrangular cross-sectional shapes, respectively. Accordingly, the reflectors (e.g., FLa, FLb, and FLc) may contact bottom surfaces and inner peripheral surfaces of the first groove portion GRa, the second groove portion GRb and the third groove portion GRc, respectively.

A plurality of reflectors (e.g., FLa, FLb, and FLc) may be provided. The number of reflectors (e.g., FLa, FLb, and FLc) may correspond to the number of groove portions (e.g., GRa, GRb, and GRc). The reflectors (e.g., FLa, FLb, and FLc) may include a first reflector FLa, a second reflector FLb, and a third reflector FLc. For example, the first reflector FLa, the second reflector FLb, and the third reflector FLc may be located on the first inorganic layer 104. The first reflector FLa, the second reflector FLb, and the third reflector FLc may be spaced apart from each other. The first reflector FLa may be accommodated in the first groove portion GRa, the second reflector FLb may be accommodated in the second groove portion GRb, and the third reflector FLc may be accommodated in the third groove portion GRc.

In an embodiment, the adhesive members (e.g., ADa, ADb, and ADc) may be located on the first inorganic layer 104. The adhesive members (e.g., ADa, ADb, and ADc) may be accommodated in the first groove portion GRa, the second groove portion GRb and the third groove portion GRc, respectively. The adhesive members (e.g., ADa, ADb, and ADc) may be located between the first inorganic layer 104 and the first reflector FLa, the second reflector FLb and the third reflector FLc, respectively. The adhesive members (e.g., ADa, ADb, and ADc) may contact bottom surfaces and inner peripheral surfaces of the first groove portion GRa, the second groove portion GRb and the third groove portion GRc, respectively. That is, the adhesive members (e.g., ADa, ADb, and ADc) may fill spaces between the first inorganic layer 104 and the first reflector FLa, the second reflector FLb and the third reflector FLc, respectively, and may adhere the first to third reflectors FLa, FLb, and FLc, respectively, to the first inorganic layer 104. In this case, the first to third reflectors FLa, FLb, and FLc, respectively, may indirectly contact the first inorganic layer 104 through the adhesive members (e.g., ADa, ADb, and ADc). For example, the adhesive member may be formed of an ITO material or a TiN material.

In an embodiment, a plurality of adhesive members (e.g., ADa, ADb, and ADc) may be provided. The number of adhesive members (e.g., ADa, ADb, and ADc) may correspond to the number of groove portions (e.g., GRa, GRb, and GRc). For example, a first adhesive member ADa, a second adhesive member ADb, and a third adhesive member ADc may be located on the first inorganic layer 104. The first adhesive member ADa, the second adhesive member ADb, and the third adhesive member ADc may be spaced apart from each other. The first adhesive member ADa may be accommodated in the first groove portion GRa, the second adhesive member ADb may be accommodated in the second groove portion GRb, and the third adhesive member ADc may be accommodated in the third groove portion GRc.

In an embodiment, the second inorganic layer 105 may be located on the first inorganic layer 104. The second inorganic layer 105 may cover upper portions of the first inorganic layer 104 and the first to third reflectors FLa, FLb, and FLc, respectively. For example, the second inorganic layer 105 may be formed of a metal oxide or a metal nitride. In detail, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZrO₂). The second inorganic layer 105 may have a double structure formed of SiOₓ/SiN_{y} or SiNₓ/SiO_{y} in some embodiments.

In an embodiment, the second inorganic layer 105 may include a 2-1 inorganic layer 1051, a 2-2 inorganic layer 1052, and a 2-3 inorganic layer 1053. The 2-1 inorganic layer 1051 may be located on the first to third reflectors FLa, FLb, and FLc, respectively, the 2-2 inorganic layer 1052 may be located on the 2-1 inorganic layer 1051, and the 2-3 inorganic layer 1053 may be located on the 2-2 inorganic layer 1052. The 2-2 inorganic layer 1052 may cover a part of the 2-1 inorganic layer 1051, and the 2-3 inorganic layer 1053 may cover a part of the 2-2 inorganic layer 1052.

In an embodiment, the 2-1 inorganic layer 1051 may overlap the first reflector FLa, the second reflector FLb, and the third reflector FLc, the 2-2 inorganic layer 1052 may overlap the second reflector FLb and the third reflector FLc, and the 2-3 inorganic layer 1053 may overlap the third reflector FLc. As shown in FIG. 3, the 2-1 inorganic layer 1051, the 2-2 inorganic layer 1052, and the 2-3 inorganic layer 1053 may be arranged in a stepped shape.

In an embodiment, the 2-1 inorganic layer 1051 and the 2-2 inorganic layer 1052 may be formed of different materials, and the 2-2 inorganic layer 1052 and the 2-3 inorganic layer 1053 may be formed of different materials. For example, the 2-1 inorganic layer 1051 may be formed of a silicon nitride (SiNₓ) material, the 2-2 inorganic layer 1052 may be formed of a silicon oxide (SiOₓ) material, and the 2-3 inorganic layer 1053 may be formed of a silicon nitride (SiNₓ) material.

In an embodiment, the organic light-emitting diodes (e.g., OLEDa, OLEDb, and OLEDc) may be located on the second inorganic layer 105. The organic light-emitting diodes (e.g., OLEDa, OLEDb, and OLEDc) may include a first pixel electrode 140a, a second pixel electrode 140b and a third pixel electrode 140c, respectively, and a first intermediate layer 150a, a second intermediate layer 150b and a third intermediate layer 150c, respectively, and a counter electrode 160. The organic light-emitting diodes (e.g., OLEDa, OLEDb, and OLEDc) may emit light. For example, the organic light-emitting diodes (e.g., OLEDa, OLEDb, and OLEDc) may emit red light, green light, or blue light.

In an embodiment, the first to third pixel electrodes 140a, 140b, and 140c, respectively, may be located on the second inorganic layer 105. The first to third pixel electrodes 140a, 140b, and 140c, respectively, may be connected to the conductive layer 130 through a contact hole formed in the first inorganic layer 104 and the second inorganic layer 105. That is, the first pixel electrode 140a, the second pixel electrode 140b and the third pixel electrode 140c may be electrically connected to the first thin-film transistor TFTa, the second thin-film transistor TFTb and the third thin-film transistor TFTc, respectively. The first to third pixel electrodes 140a, 140b, and 140c, respectively, may be formed of a light-transmitting conductive oxide material such as ITO, In₂O₃, or IZO.

In an embodiment, the pixel-defining film 106 may be located on the second inorganic layer 105. The pixel-defining film 106 may cover edges of the first to third pixel electrodes 140a, 140b, and 140c, respectively. The pixel-defining film 106 may have an opening corresponding to a pixel, and at least a central portion of each of the first to third pixel electrodes 140a, 140b, and 140c, respectively, may be exposed through the opening. The pixel-defining film 106 may include an organic material such as polyimide or hexamethyldisiloxane (HMDSO). Also, a spacer (not shown) may be located on the pixel-defining film 106.

In an embodiment, the first to third intermediate layers 150a, 150b, and 150c, respectively, may be located in the openings of the pixel-defining film 106. The first to third intermediate layers 150a, 150b, and 150c, respectively, may include a low molecular weight material or a high molecular weight material. When the first to third intermediate layers 150a, 150b, and 150c, respectively, include a low molecular weight material, the first to third intermediate layers 150a, 150b, and 150c, respectively, may include a hole injection layer, a hole transport layer, an emission layer, an electron transport layer, and/or an electron injection layer. When the first to third intermediate layers 150a, 150b, and 150c, respectively, include a high molecular weight material, the first to third intermediate layers 150a, 150b, and 150c, respectively, may generally have a structure including a hole transport layer and an emission layer.

In an embodiment, the counter electrode 160 may include a light-transmitting conductive layer 130 formed of a light-transmitting conductive oxide such as ITO, In₂O₃, or IZO. The first to third pixel electrodes 140a, 140b, and 140c, respectively, may be used as anodes, and the counter electrode 160 may be used as a cathode. Polarities of the electrodes may be applied in reverse.

In an embodiment, the counter electrode 160 may be located in the display area DA (see FIG. 1), and may be located over an entire surface of the display area DA (see FIG. 1). That is, the counter electrode 160 may be integrally formed to cover a plurality of pixels. The counter electrode 160 may be in electrical contact with a common power supply line (not shown) located in the peripheral area PA (see FIG. 1).

In an embodiment, a plurality of organic light-emitting diodes (e.g., OLEDa, OLEDb, and OLEDc) may be provided. The number of organic light-emitting diodes (e.g., OLEDa, OLEDb, and OLEDc) may correspond to the number of reflectors (e.g., FLa, FLb, and FLc). The organic light-emitting diodes (e.g., OLEDa, OLEDb, and OLEDc) may include a first organic light-emitting diode OLEDa, a second organic light-emitting diode OLEDb, and a third organic light-emitting diode OLEDc.

In an embodiment, the first organic light-emitting diode OLEDa, the second organic light-emitting diode OLEDb, and the third organic light-emitting diode OLEDc may be located on the second inorganic layer 105. The first organic light-emitting diode OLEDa, the second organic light-emitting diode OLEDb, and the third organic light-emitting diode OLEDc may be spaced apart from each other. The first organic light-emitting diode OLEDa may be located on the 2-1 inorganic layer 1051, the second organic light-emitting diode OLEDb may be located on the 2-2 inorganic layer 1052, and the third organic light-emitting diode OLEDc may be located on the 2-3 inorganic layer 1053.

In an embodiment, the first organic light-emitting diode OLEDa may include the first pixel electrode 140a, the first intermediate layer 150a, and the counter electrode 160. The first pixel electrode 140a may be located on the 2-1 inorganic layer 1051. The first pixel electrode 140a may be connected to the conductive layer 130 through a contact hole formed in the first inorganic layer 104 and the 2-1 inorganic layer 1051. That is, the first pixel electrode 140a may be electrically connected to the first thin-film transistor TFTa. The first intermediate layer 150a may be located on the first pixel electrode 140a.

In an embodiment, the second organic light-emitting diode OLEDb may include the second pixel electrode 140b, the second intermediate layer 150b, and the counter electrode 160. The second pixel electrode 140b may be located on the 2-2 inorganic layer 1052. The second pixel electrode 140b may be connected to the conductive layer 130 through a contact hole formed in the first inorganic layer 104 and the 2-2 inorganic layer 1052. That is, the second pixel electrode 140b may be electrically connected to the second thin-film transistor TFTb. The second intermediate layer 150b may be located on the second pixel electrode 140b.

In an embodiment, the third organic light-emitting diode OLEDc may include the third pixel electrode 140c, the third intermediate layer 150c, and the counter electrode 160. The third pixel electrode 140c may be located on the 2-3 inorganic layer 1053. The third pixel electrode 140c may be connected to the conductive layer 130 through a contact hole formed in the first inorganic layer 104 and the 2-3 inorganic layer 1053. That is, the third pixel electrode 140c may be electrically connected to the third thin-film transistor TFTc. The third intermediate layer 150c may be located on the third pixel electrode 140c.

In an embodiment, light emitted from the first organic light-emitting diode OLEDa, the second organic light-emitting diode OLEDb and the third organic light-emitting diode OLEDc may resonate by being reflected by the first reflector FLa, the second reflector FLb and the third reflector FLc, respectively, and the counter electrode 160. That is, the first to third reflectors FLa, FLb, and FLc, respectively, and the counter electrode 160 may form an optical resonance structure. A distance between the first reflector Fla, the second reflector FLb and the third reflector FLc and the first organic light-emitting diode OLEDa, the second organic light-emitting diode OLEDb and the third organic light-emitting diode OLEDc, respectively, may correspond to a wavelength region of light emitted from the first organic light-emitting diode OLEDa, the second organic light-emitting diode OLEDb and the third organic light-emitting diode OLEDc, respectively.

In an embodiment, in this structure, a distance d1 from the first reflector FLa to the first organic light-emitting diode OLEDa, a distance d2 from the second reflector FLb to the second organic light-emitting diode OLEDb, and a distance d3 from the third reflector FLc to the third organic light-emitting diode OLEDc may be different from each other. Accordingly, the first organic light-emitting diode OLEDa, the second organic light-emitting diode OLEDb, and the third organic light-emitting diode OLEDc may emit light having different wavelengths.

In an embodiment, the distance d1 from the first reflector FLa to the first organic light-emitting diode OLEDa, the distance d2 from the second reflector FLb to the second organic light-emitting diode OLEDb, and the distance d3 from the third reflector FLc to the third organic light-emitting diode OLEDc may sequentially increase. Accordingly, wavelengths of light emitted from the first organic light-emitting diode OLEDa, the second organic light-emitting diode OLEDb, and the third organic light-emitting diode OLEDc may sequentially decrease. For example, the first organic light-emitting diode OLEDa may emit red light, the second organic light-emitting diode OLEDb may emit green light, and the third organic light-emitting diode OLEDc may emit blue light.

In an embodiment, a thin-film encapsulation layer TFE may cover the entire display area DA (see FIG. 1) and may extend to the peripheral area PA (see FIG. 1) to cover at least a part of the peripheral area PA (see FIG. 1).

In an embodiment, the thin-film encapsulation layer TFE may extend to the outside of the common power supply line (not shown). The thin-film encapsulation layer TFE may include a first inorganic encapsulation layer 310, a second inorganic encapsulation layer 330, and an organic encapsulation layer 320 located between the first inorganic encapsulation layer 310 and the second inorganic encapsulation layer 330. Each of the first and second inorganic encapsulation layers 310 and 330 may include at least one inorganic material from among aluminum oxide, titanium oxide, tantalum oxide, hafnium oxide, zinc oxide, silicon oxide, silicon nitride, and silicon oxynitride.

In an embodiment, each of the first inorganic encapsulation layer 310 and the second inorganic encapsulation layer 330 may have a single or multi-layer structure including the above material. The first inorganic encapsulation layer 310 and the second inorganic encapsulation layer 330 may include the same material or different materials. Thicknesses of the first inorganic encapsulation layer 310 and the second inorganic encapsulation layer 330 may be different from each other. A thickness of the first inorganic encapsulation layer 310 may be greater than a thickness of the second inorganic encapsulation layer 330. In another embodiment, a thickness of the second inorganic encapsulation layer 330 may be greater than a thickness of the first inorganic encapsulation layer 310, or thicknesses of the first inorganic encapsulation layer 310 and the second inorganic encapsulation layer 330 may be the same.

In an embodiment, the organic encapsulation layer 320 may include a monomer-based material or a polymer-based material. Examples of the polymer-based material may include an acrylic resin, an epoxy resin, polyimide, and polyethylene. In an embodiment, the organic encapsulation layer 320 may include acrylate.

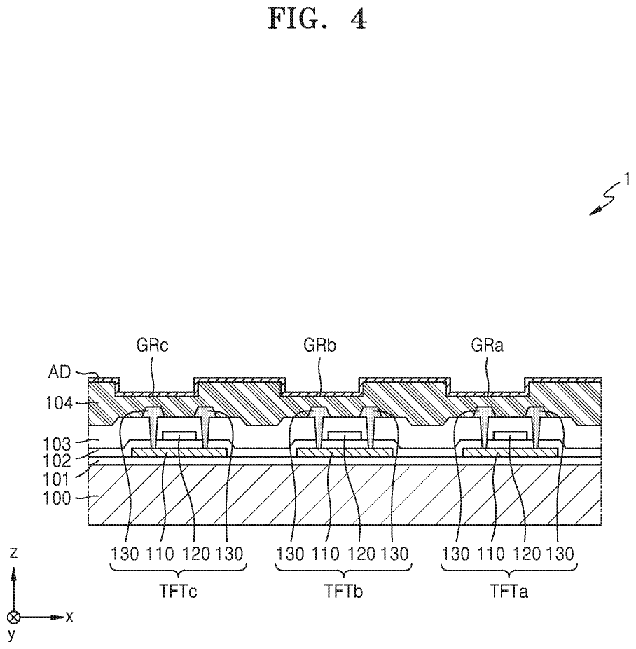

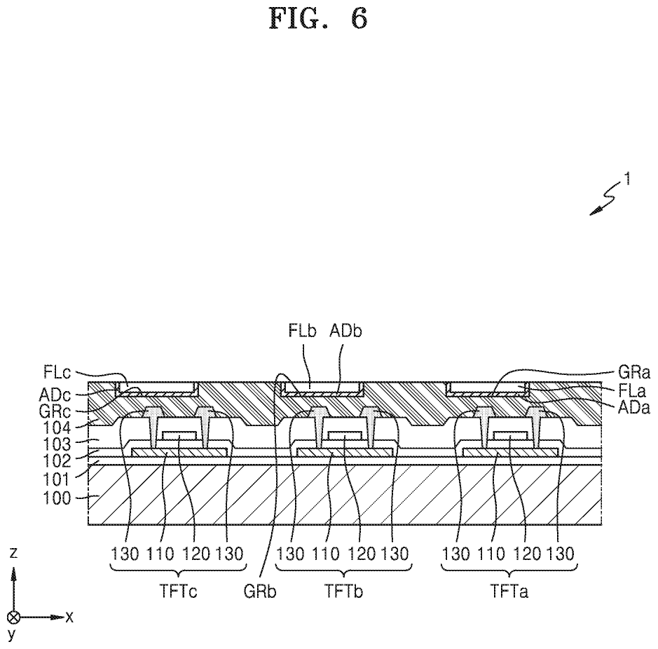

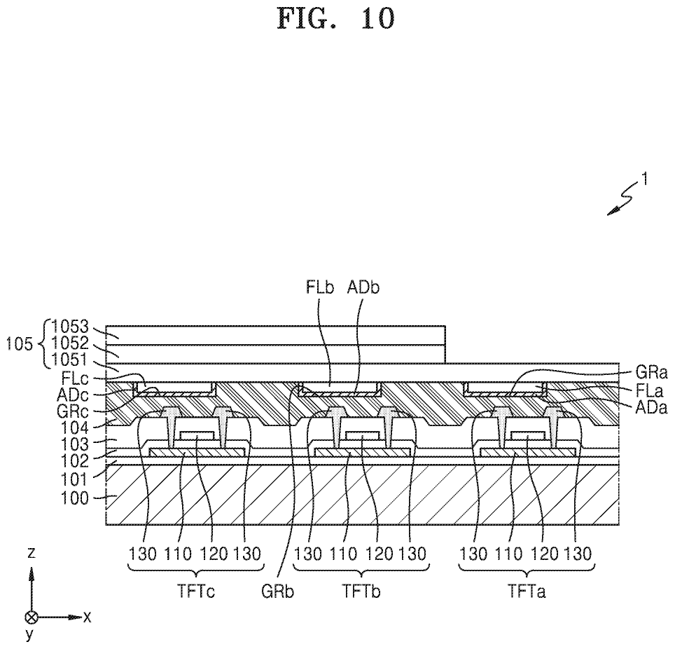

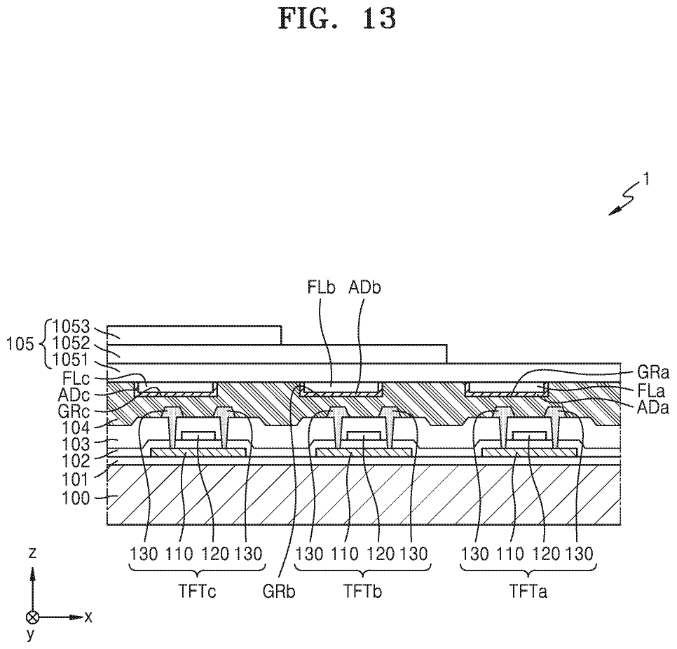

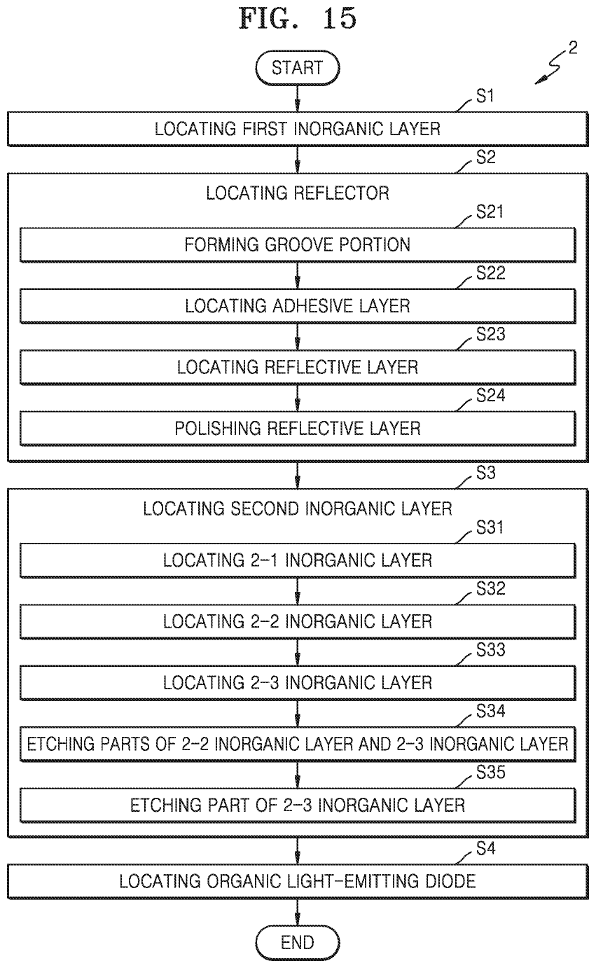

FIGS. 4 to 14 are schematic cross-sectional views illustrating a part of the display apparatus 1, according to an embodiment. FIG. 15 is a schematic flowchart illustrating a method 2 of manufacturing a display apparatus, according to an embodiment.

In FIGS. 4 to 15, the same members are denoted by the same reference numerals as those in FIG. 3, and thus, a repeated description thereof will be omitted.

In an embodiment and referring to FIGS. 4 to 15, the method 2 of manufacturing a display apparatus may include operation S1 of locating the first inorganic layer 104 on the substrate 100, operation S2 of locating the first to third reflectors FLa, FLb, and FLc on the first inorganic layer 104, operation S3 of locating the second inorganic layer 105 on the first to third reflectors FLa, FLb, and FLc, respectively, and operation S4 of locating the first to third organic light-emitting diodes OLEDa, OLEDb, and OLEDc, respectively, on the second inorganic layer 105.

In an embodiment and referring to FIGS. 4 and 15, in operation S1, the first inorganic layer 104 may be located on the substrate 100.

In an embodiment, the buffer layer 101 may be located on the substrate 100, the gate insulating film 102 may be located on the buffer layer 101, the interlayer insulating film 103 may be located on the gate insulating film 102, and the first inorganic layer 104 may be located on the interlayer insulating film 103.

In an embodiment, the first to third thin-film transistors TFTa, TFTb, and TFTc, respectively may be located on the buffer layer 101. A plurality of thin-film transistors (e.g., TFTa, TFTb, and TFTc) may be provided. For example, the plurality of thin-film transistors (e.g., TFTa, TFTb, and TFTc) may include the first thin-film transistor TFTa, the second thin-film transistor TFTb, and the third thin-film transistor TFTc. Each of the first to third thin-film transistors TFTa, TFTb, and TFTc, respectively, may include the semiconductor layer 110, the gate layer 120, and the conductive layer 130.

In an embodiment and referring to FIGS. 4 to 6 and 15, in operation S2, the first to third reflectors FLa, FLb, and FLc, respectively, may be located on the substrate 100. The first to third reflectors FLa, FLb, and FLc, respectively, may be arranged by using a damascene process.

In an embodiment and referring to FIGS. 4 and 15, operation S2 of locating the first reflector FLa, the second reflector FLb and the third reflector FLc may include operation S21 of forming the first groove portion GRa, the second groove portion GRb and the third groove portion GRc, respectively, in the first inorganic layer 104 and operation S22 of locating an adhesive layer AD on the first inorganic layer 104 to cover the first inorganic layer 104.

In an embodiment, operation S21 of forming the first to third groove portions GRa, GRb, and GRc, respectively, may include a photolithography process. The first to third groove portions GRa, GRb, and GRc, respectively, may be formed in the first inorganic layer 104 by performing dry etching or wet etching on the first inorganic layer 104. A plurality of groove portions (e.g., GRa, GRb, and GRc) may be provided. For example, the plurality of groove portions (e.g., GRa, GRb, and GRc) may include the first groove portion GRa, the second groove portion GRb, and the third groove portion GRc.

In an embodiment, the adhesive layer AD may cover the first inorganic layer 104, and a part of the adhesive layer AD may be accommodated in the first to third groove portions GRa, GRb, and GRc. The adhesive layer AD may contact inner peripheral surfaces of the first to third groove portions GRa, GRb, and GRc, respectively. The adhesive layer AD may have an uneven cross-sectional shape to correspond to shapes of the first to third groove portions GRa, GRb, and GRc, respectively.

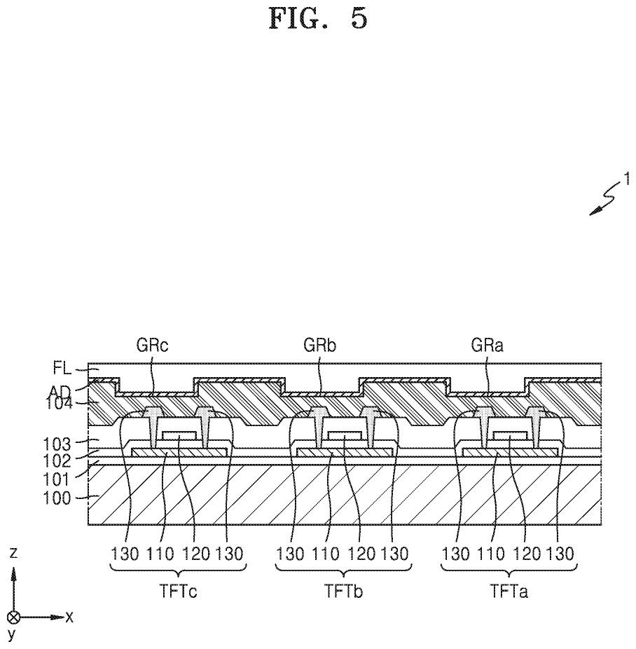

In an embodiment and referring to FIGS. 5 and 15, operation S2 of locating the first to third reflectors FLa, FLb, and FLc, respectively, may include operation S23 of locating a reflective layer FL on the first inorganic layer 104 to cover the first inorganic layer 104. In this case, because the adhesive layer AD covers the first inorganic layer 104, operation S23 of locating the reflective layer FL on the first inorganic layer 104 may be operation S23 of locating the reflective layer FL on the adhesive layer AD. That is, the adhesive layer AD may be located between the first inorganic layer 104 and the reflective layer FL. A part of the reflective layer FL may be accommodated in the first to third groove portions GRa, GRb, and GRc, respectively. For example, the reflective layer FL may include a silver (Ag) material.

In an embodiment and referring to FIGS. 5, 6, and 15, operation S2 of locating the first to third reflectors FLa, FLb, and FLc, respectively, may include operation S24 of polishing the reflective layer FL. A polishing process of the reflective layer FL may include chemical mechanical polishing (CMP). Upper portions of the reflective layer FL and the adhesive layer AD may be polished and removed. In this process, the polished reflective layer FL may be divided into the first reflector FLa, the second reflector FLb, and the third reflector FLc. Also, the polished adhesive layer AD may be divided into the first adhesive member ADa, the second adhesive member ADb, and the third adhesive member ADc. That is, operation S2 of locating the first reflector FLa, the second reflector FLb and the third reflector FLc may be an operation of locating the first reflector FLa, the second reflector FLb, and the third reflector FLc on the first inorganic layer 104 to be spaced apart from each other.

In an embodiment, when the reflective layer FL is formed of a silver (Ag) material, drying etching of the reflective layer FL may be difficult. Also, when the reflective layer FL is wet etched, skew may occur due to isotropic etching of the reflective layer FL, thereby making it difficult to fine pattern of the first to third reflectors FLa, FLb, and FLc, respectively. In an embodiment, because the reflective layer FL is polished by using a damascene process, the precision of patterning the first to third reflectors FLa, FLb, and FLc, respectively, may be improved.

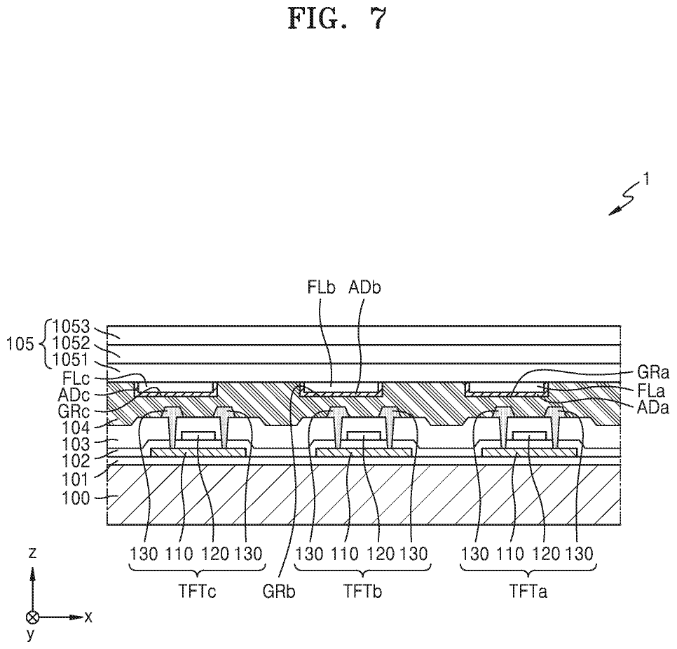

In an embodiment and referring to FIGS. 7 to 13 and 15, in operation S3, the second inorganic layer 105 may be located on the first to third reflectors FLa, FLb, and FLc.

First, referring to FIGS. 7 and 15, operation S3 of locating the second inorganic layer 105 on the first to third reflectors FLa, FLb, and FLc, respectively, may include operation S31 of locating the 2-1 inorganic layer 1051 on the first to third reflectors FLa, FLb, and FLc, respectively, operation S32 of locating the 2-2 inorganic layer 1052 on the 2-1 inorganic layer 1051, and operation S33 of locating the 2-3 inorganic layer 1053 on the 2-2 inorganic layer 1052. The 2-1 inorganic layer 1051 may be located on the first reflector FLa, the second reflector FLb, and the third reflector FLc. The 2-2 inorganic layer 1052 may cover the 2-1 inorganic layer 1051, and the 2-3 inorganic layer 1053 may cover the 2-2 inorganic layer 1052.

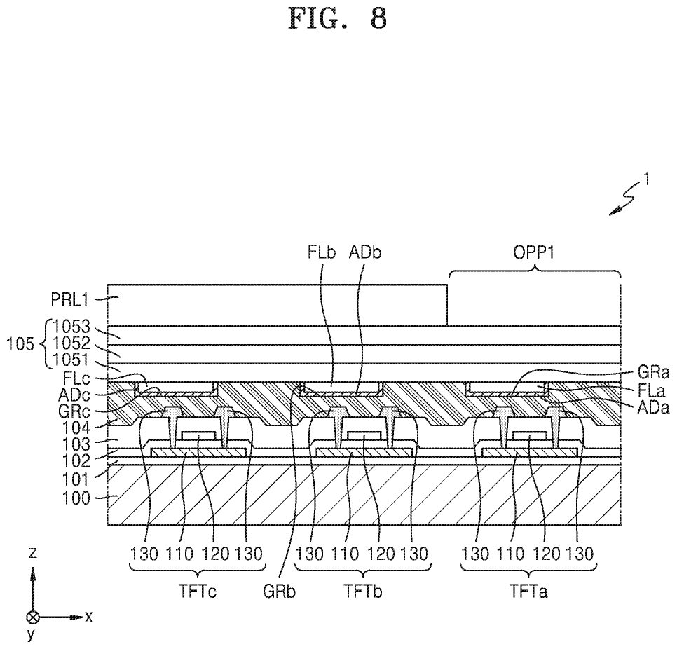

In an embodiment and referring to FIGS. 8 to 10 and 15, operation S3 of locating the second inorganic layer 105 on the first to third reflectors FLa, FLb, and FLc, respectively, may include operation S34 of etching parts of the 2-2 inorganic layer 1052 and the 2-3 inorganic layer 1053 overlapping the first reflector FLa. Operation S34 of etching parts of the 2-2 inorganic layer 1052 and the 2-3 inorganic layer 1053 may include a photolithography process. Parts of the 2-2 inorganic layer 1052 and the 2-3 inorganic layer 1053 may be dry etched or wet etched.

In an embodiment and referring to FIGS. 8 and 15, a first photoresist layer PRL1 may be located on the 2-3 inorganic layer 1053. The first photoresist layer PRL1 may include a first photo-opening OPP1. The first photo-opening OPP1 may overlap the first reflector FLa.

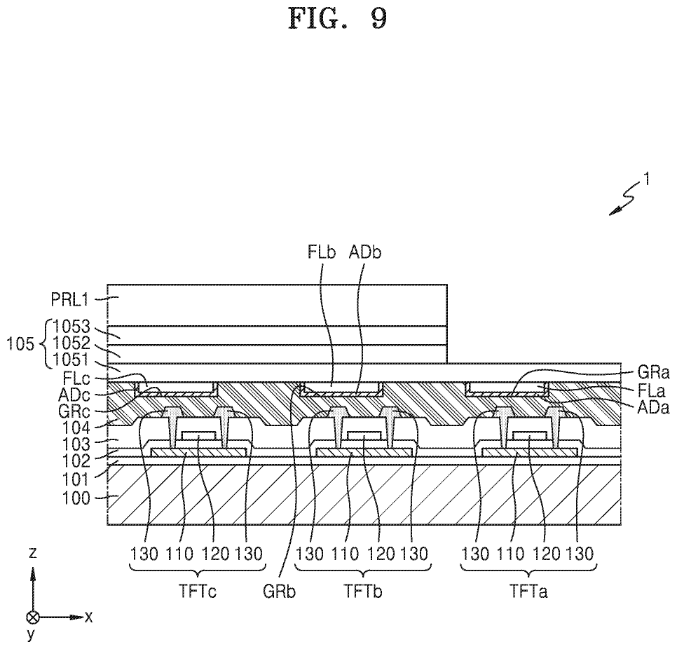

In an embodiment and referring to FIGS. 9 and 15, the 2-2 inorganic layer 1052 and the 2-3 inorganic layer 1053 overlapping the first photo-opening OPP1 may be etched. The 2-1 inorganic layer 1051 and the 2-2 inorganic layer 1052 may be formed of different materials. Accordingly, a phenomenon where the 2-1 inorganic layer 1051 is etched during a process of etching the 2-2 inorganic layer 1052 may be reduced.

In an embodiment and referring to FIGS. 9, 10, and 15, when parts of the 2-2 inorganic layer 1052 and the 2-3 inorganic layer 1053 are etched, the first photoresist layer PRL1 may be removed.

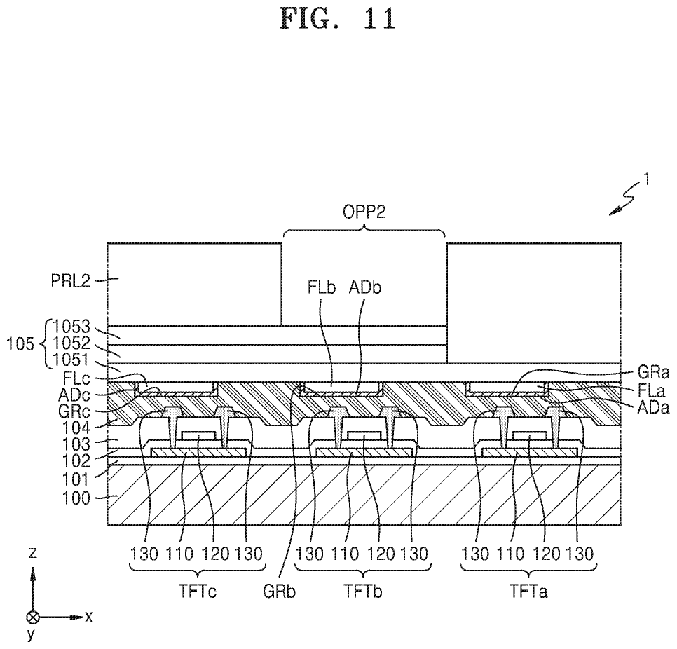

In an embodiment and referring to FIGS. 11 to 13 and 15, operation S3 of locating the second inorganic layer 105 on the first to third reflectors FLa, FLb, and FLc, respectively, may include operation S35 of etching a part of the 2-3 inorganic layer 1053 overlapping the second reflector FLb. Operation S35 of etching a part of the 2-3 inorganic layer 1053 may include a photolithography process. A part of the 2-3 inorganic layer 1053 may be dry etched or wet etched.

In an embodiment and referring to FIGS. 11 and 15, a second photoresist layer PRL2 may be located on the second inorganic layer 105. In detail, the second photoresist layer PRL2 may be located on the 2-1 inorganic layer 1051 and the 2-3 inorganic layer 1053. The second photoresist layer PRL2 may include a second photo-opening OPP2. The second photo-opening OPP2 may be located in the second photoresist layer PRL2 to overlap the second reflector FLb.

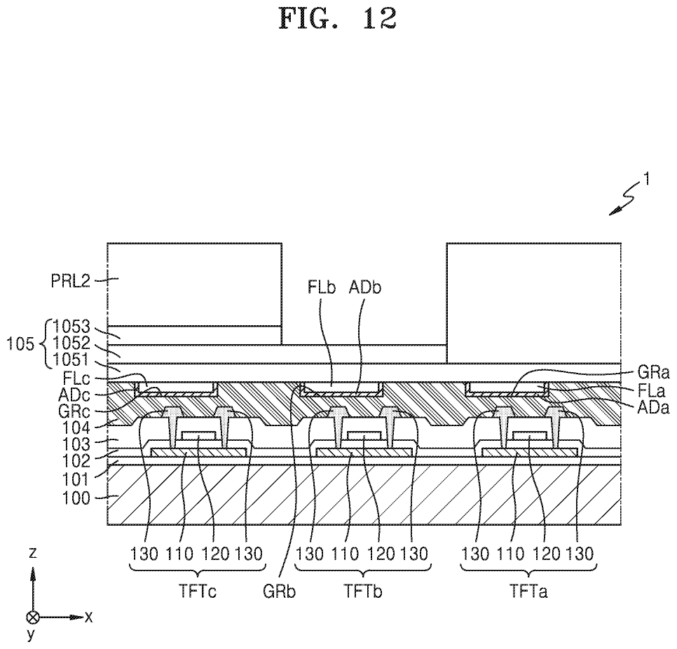

In an embodiment and referring to FIGS. 12 and 15, the 2-3 inorganic layer 1053 overlapping the second photo-opening OPP2 may be etched. The 2-2 inorganic layer 1052 and the 2-3 inorganic layer 1053 may be formed of different materials. Accordingly, a phenomenon where the 2-2 inorganic layer 1052 is etched during a process of etching the 2-3 inorganic layer 1053 may be reduced.

In an embodiment and referring to FIGS. 12, 13, and 15, when parts of the 2-2 inorganic layer 1052 and the 2-3 inorganic layer 1053 are etched, the first photoresist layer PRL2 may be removed.

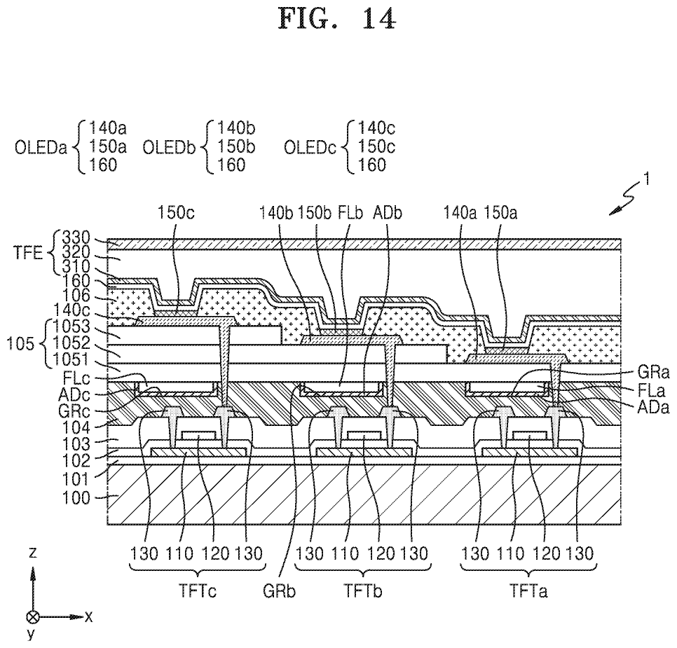

In an embodiment and referring to FIGS. 14 and 15, in operation S4, the first to third organic light-emitting diodes OLEDa, OLEDb, and OLEDc, respectively, may be located on the second inorganic layer 105. The first organic light-emitting diode OLEDa may be located on the 2-1 inorganic layer 1051 to overlap the first reflector FLa, the second organic light-emitting diode OLEDb may be located on the 2-2 inorganic layer 1052 to overlap the second reflector FLb, and the third organic light-emitting diode OLEDc may be located on the 2-3 inorganic layer 1053 to overlap the third reflector FLc. The pixel-defining film 106 and the thin-film encapsulation layer TFE may be located on the first to third organic light-emitting diodes OLEDa, OLEDb, and OLEDc, respectively.

According to an embodiment, a reflector may be more precisely processed by using a damascene process.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the invention. Accordingly, the scope of the various embodiments of the invention should be interpreted to include, in addition to the embodiments disclosed herein, all alterations or modifications that may be derived from the technical ideas of the various embodiments. Moreover, the embodiments or parts of the embodiments may be combined in whole or in part without departing from the scope of the invention.

What is claimed is:

1. A method of manufacturing a display apparatus, the method comprising:
locating a first inorganic layer on a substrate;
locating a reflector on the first inorganic layer;
locating a second inorganic layer on the reflector; and
locating an organic light-emitting diode on the second inorganic layer,
wherein the locating of the reflector comprises:
forming a groove portion in the first inorganic layer;
locating a reflective layer on the first inorganic layer to cover the first inorganic layer; and
polishing the reflective layer.

2. The method of claim 1, wherein the locating the reflector comprises locating an adhesive layer on the first inorganic layer to cover the first inorganic layer and locating the reflective layer on the adhesive layer.

3. The method of claim 2, wherein the adhesive layer contacts an inner peripheral surface of the groove portion.

4. The method of claim 1, wherein the reflector comprises a silver (Ag) material.

5. The method of claim 1, wherein the reflector comprises:
a first reflector;
a second reflector spaced apart from the first reflector; and
a third reflector spaced apart from the first reflector and the second reflector,
wherein the organic light-emitting diode comprises:
a first organic light-emitting diode overlapping the first reflector;
a second organic light-emitting diode overlapping the second reflector; and
a third organic light-emitting diode overlapping the third reflector.

6. The method of claim 5, wherein the locating of the second inorganic layer comprises:
locating a 2-1 inorganic layer on the reflector;
locating a 2-2 inorganic layer on the 2-1 inorganic layer; and
locating a 2-3 inorganic layer on the 2-2 inorganic layer,
wherein the first organic light-emitting diode is located on the 2-1 inorganic layer,
the second organic light-emitting diode is located on the 2-2 inorganic layer, and
the third organic light-emitting diode is located on the 2-3 inorganic layer.

7. The method of claim 6, wherein the locating of the second inorganic layer further comprises:
etching parts of the 2-2 inorganic layer and the 2-3 inorganic layer overlapping the first reflector; and
etching a part of the 2-3 inorganic layer overlapping the second reflector.

8. The method of claim 7, wherein each of the etching parts of the 2-2 inorganic layer and the 2-3 inorganic layer and the etching a part of the 2-3 inorganic layer comprises a photolithography process.

9. The method of claim 6, wherein a distance from the first reflector to the first organic light-emitting diode, a distance from the second reflector to the second organic light-emitting diode, and a distance from the third reflector to the third organic light-emitting diode sequentially increase.

10. The method of claim 6, wherein the 2-1 inorganic layer and the 2-2 inorganic layer comprise different materials.

11. The method of claim 6, wherein the 2-2 inorganic layer and the 2-3 inorganic layer comprise different materials.

12. The method of claim 6, wherein
the first organic light-emitting diode emits red light,
the second organic light-emitting diode emits green light, and
the third organic light-emitting diode emits blue light.

13. A method of manufacturing a display apparatus, the method comprising:
locating a first inorganic layer on a substrate;
locating a first reflector, a second reflector, and a third reflector on the first inorganic layer to be spaced apart from each other;
locating a 2-1 inorganic layer on the first reflector, the second reflector, and the third reflector;
locating a 2-2 inorganic layer on the 2-1 inorganic layer;
locating a 2-3 inorganic layer on the 2-2 inorganic layer;
etching parts of the 2-2 inorganic layer and the 2-3 inorganic layer overlapping the first reflector;
etching a part of the 2-3 inorganic layer overlapping the second reflector;
locating a first organic light-emitting diode on the 2-1 inorganic layer to overlap the first reflector;
locating a second organic light-emitting diode on the 2-2 inorganic layer to overlap the second reflector; and
locating a third organic light-emitting diode on the 2-3 inorganic layer to overlap the third reflector.

14. The method of claim 13, wherein a distance from the first reflector to the first organic light-emitting diode, a distance from the second reflector to the second organic light-emitting diode, and a distance from the third reflector to the third organic light-emitting diode sequentially increase.

15. The method of claim 13, wherein the 2-1 inorganic layer and the 2-2 inorganic layer comprise different materials.

16. The method of claim 13, wherein the 2-2 inorganic layer and the 2-3 inorganic layer comprise different materials.

17. The method of claim 13, wherein
the first organic light-emitting diode emits red light,
the second organic light-emitting diode emits green light, and
the third organic light-emitting diode emits blue light.

18. The method of claim 13, wherein an adhesive layer is located between the first inorganic layer and the first reflector, between the first inorganic layer and the second reflector, and between the first inorganic layer and the third reflector.

19. The method of claim 13, wherein each of the first reflector, the second reflector, and the third reflector comprises a silver (Ag) material.

20. The method of claim 13, wherein each of the etching parts of the 2-2 inorganic layer and the 2-3 inorganic layer and the etching a part of the 2-3 inorganic layer comprises a photolithography process.
